(19) United States
(12) Patent Application Publication
(10) Pub. No.: US 2023/0246045 A1
(43) Pub. Date: Aug. 3, 2023

(54) IMAGE SENSOR

(71) Applicant: SAMSUNG ELECTRONICS CO., LTD., SUWON-SI, GYEONGGI-DO (KR)

(72) Inventors: Taehan Kim, Hwaseong-si (KR); Dongmin Keum, Daegu (KR); Bumsuk Kim, Hwaseong-si (KR); Kwanghee Lee, Hwaseong-si (KR); Yunki Lee, Hwaseong-si (KR); Yeaju Jang, Seoul (KR)

(21) Appl. No.: 18/147,092

(22) Filed: Dec. 28, 2022

(30) Foreign Application Priority Data
Jan. 28, 2022 (KR) 10-2022-0013620

(51) Int. Cl. H01L 27/146

(52) U.S. Cl. CPC H01L 27/14621; H01L 27/14645; H01L 27/14627

(57) ABSTRACT

There is provided an image sensor including first to fourth color filter layers arranged on a substrate and first to seventh microlenses arranged on the first to fourth color filter layers. The first microlenses vertically overlap diagonal components of a first submatrix comprised of green-red subpixels. The second and third group of microlenses vertically overlap off-diagonal components of the first submatrix comprised of green-red subpixels. A horizontal area of each of the second group of microlenses is less than a horizontal area of each of the first microlenses and a horizontal area of each of the third group of microlenses is greater than a horizontal area of each of the first microlenses.

### CROSS-REFERENCE TO RELATED APPLICATION

This application claims priority under 35 U.S.C. § 119 to Korean Patent Application No. 10-2022-0013620, filed on Jan. 28, 2022, in the Korean Intellectual Property Office, the disclosure of which is incorporated by reference herein in its entirety.

### TECHNICAL FIELD

Embodiments of the inventive concept relate to an image sensor with improved resolution.

### DISCUSSION OF RELATED ART

An image sensor is a device capturing a two or three-dimensional image of an object. The image sensor generates an image of the object by using a photoelectric conversion element reacting in accordance with the intensity of light reflected from the object. Recently, a complementary metal-oxide semiconductor (CMOS)-based image sensor capable of implementing high resolution has been widely used.

### SUMMARY

Embodiments of the inventive concept relate to an image sensor with improved resolution.

According to an aspect of the inventive concept, an image sensor includes a plurality of color filter layers, including first to fourth color filter layers arranged on a substrate, the color filter layers being arranged horizontally adjacent to one another, in which the first and fourth color filter layers transmit visible light components of different wavelength bands from incident visible light components passing through the second and third color filter layers. The image sensor further includes a plurality of microlenses including first to seventh microlenses. Wherein the plurality of microlenses are arranged on the first to fourth color filter layers. In the substrate, green-red subpixels overlapping the first color filter layer in a third direction perpendicular to the substrate form a first submatrix, red subpixels overlapping the second color filter layer in a third direction perpendicular to the substrate form a second submatrix, blue subpixels overlapping the third color filter layer in a third direction perpendicular to the substrate form a third submatrix, and green-blue subpixels overlapping the fourth color filter layer in a third direction perpendicular to the substrate form a fourth submatrix. The first microlenses overlap diagonal subpixel components of the first submatrix comprised of the green-red subpixels. The second and third microlenses overlap off-diagonal subpixel components of the first submatrix comprised of the green-red subpixels. A horizontal area of each of the second microlenses is less than a horizontal area of each of the first microlenses. A horizontal area of each of the third microlenses is greater than a horizontal area of each of the first microlenses.

According to an aspect of the inventive concept, there is provided an image sensor. The image sensor includes a substrate in which a plurality of green-red subpixels are arranged to form a first submatrix, a plurality of red subpixels are arranged to form a second submatrix, a plurality of blue subpixels are arranged to form a third submatrix, and a plurality of green-blue subpixels are arranged to form a fourth submatrix. First to fourth color filter layers are arranged on the substrate adjacent to one another, and first to seventh microlenses are arranged on the first to fourth color filter layers. The fourth microlenses vertically overlap diagonal components of the second submatrix comprised of the plurality of red subpixels. The fifth and sixth microlenses vertically overlap off-diagonal components of the second submatrix comprised of the plurality of red subpixels. A length in a first direction of each of the fourth microlenses is substantially equal to a length in a second direction of each of the fourth microlenses. A length in a first direction of each of the fifth microlenses is greater than a length in a second direction of each of the fifth microlenses. A length in a second direction of each of the sixth microlenses is greater than a length in the first direction of each of the sixth microlenses.

According to an aspect of the inventive concept, there is provided an image sensor. The image sensor includes a first color filter layer transmitting green light, a second color filter layer transmitting red light, a third color filter layer transmitting blue light, and a fourth color filter layer transmitting green light. The first to third microlenses are arranged on the first and fourth color filter layers, and fourth to sixth microlenses are arranged on the second color filter layer. The first to fourth color filter layers are arranged in a matrix extending in first and second directions in the same plane to form a Bayer pattern. The third microlenses are arranged closer to the second color filter layer than the second microlenses. The second microlenses are arranged closer to the third color filter layer than the third microlenses. A horizontal area of each of the third microlenses is greater than a horizontal area of each of the first microlenses. A horizontal area of each of the second microlenses is less than a horizontal area of each of the first microlenses.

### BRIEF DESCRIPTION OF THE DRAWINGS

Embodiments of the inventive concept will be more clearly understood from the following detailed description taken in conjunction with the accompanying drawings in which:

FIG. 1 is a block diagram illustrating an image sensor according to an embodiment of the inventive concept;

FIG. 2 is a circuit diagram illustrating a plurality of subpixels included in an image sensor according to an embodiment of the inventive concept;

FIG. 3 illustrates a layout of a pixel array of an image sensor according to an embodiment of the inventive concept;

FIG. 4A is a cross-sectional view taken along the line 3A-3A′ of FIG. 3;

FIG. 4B is a cross-sectional view taken along the line 3B-3B′ of FIG. 3;

FIG. 4C is a cross-sectional view taken along the line 3C-3C′ of FIG. 3;

FIG. 4D is a cross-sectional view taken along the line 3D-3D′ of FIG. 3;

FIG. 5 is a plan view illustrating a pixel array according to another embodiment of the inventive concept;

FIG. 6 is a partial plan view illustrating enlargements of first, second, fifth, and sixth red subpixels of FIG. 5; and

FIG. 7 is a plan view illustrating a pixel array according to another embodiment of the inventive concept.

### DETAILED DESCRIPTION OF THE EMBODIMENTS

Embodiments of the inventive concept will be described more fully hereinafter with reference to the accompanying drawings. Like reference numerals may refer to like elements throughout and accompanying drawings. In the drawings, thicknesses or sizes of the respective layers may be exaggerated for convenience and may be different from real shapes and ratios.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

As used herein, the singular forms “a”, “an” and “the” are intended to include the plural forms as well, unless the context clearly indicates otherwise.

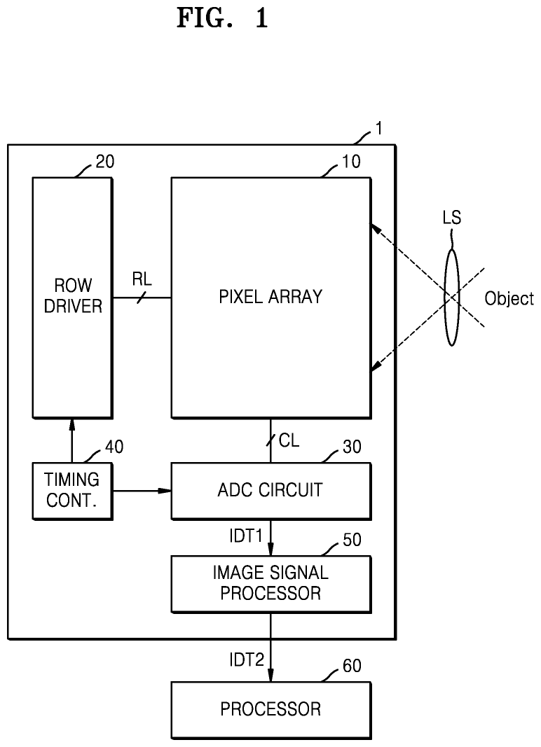

FIG. 1 is a block diagram illustrating an image sensor 1 according to an embodiment of the inventive concept. The image sensor 1 may be mounted in an electronic device having an image-sensing function or light-sensing function. For example, the image sensor 1 may be mounted in an electronic device, such as a camera, a smartphone, a wearable device, the internet of things (IoT), a personal computer (PC), a personal digital assistant (PDA), a portable multimedia player (PMP), or a navigator. In addition, the image sensor 1 may also be applied to a vehicle, furniture, a manufacturing facility, a door, or any one of a variety of measuring instruments.

The image sensor 1 may include a pixel array 10, a row driver 20, an analog-to-digital conversion (ADC) circuit 30, a timing controller 40, and an image signal processor 50.

In operation, the pixel array 10 may receive a light signal reflected from an object incident through a lens LS and may convert the incident light signal into an electrical signal. The pixel array 10 may be implemented by a complementary metal oxide semiconductor (CMOS). However, the inventive concept is not limited thereto. The pixel array 10 may be a part of a charge coupled-device (CCD) chip.

The pixel array 10 includes a plurality of row lines RL, a plurality of column lines CL (or output lines), and a plurality of pixels connected to the plurality of row lines RL and the plurality of column lines CL and arranged in M rows and N columns. In this example, the number of pixels may be M×N.

Each of the plurality of pixels may sense the received light signal by using a photoelectric conversion element. Each of the plurality of pixels may detect an amount of incident light signal and may output an electrical signal representing the detected amount of light signal.

The row driver 20 may generate a plurality of control signals capable of controlling operations of the plurality of pixels P arranged in each row under control of the timing controller 40. The row driver 20 may provide the plurality of control signals to the plurality of pixels of the pixel array 10 through the plurality of row lines RL, respectively. The pixel array 10 may be driven in units of rows in response to the plurality of control signals provided by the row driver 20.

In accordance with control of the row driver 20, the pixel array 10 may output a plurality of sensing signals through the plurality of column lines CL.

The ADC circuit 30 may convert the plurality of sensing signals from analog to digital. The sensing signals may be received through the plurality of column lines CL, respectively. The ADC circuit 30 may include a number of analog-to-digital converters (ADC) that respectively correspond to the plurality of column lines CL. The ADCs may convert the plurality of sensing signals received through the plurality of corresponding column lines CL into pixel values. In accordance with an operational mode of the image sensor 1, the pixel values may represent the amount of light component being sensed by the plurality of pixels.

Each of the ADCs may include a correlated double sampling (CDS) circuit for sampling and holding a received signal. The CDS circuit may double sample a noise signal and a sensing signal when the plurality of pixels are in reset states and may output a signal corresponding to a difference between the sensing signal and the noise signal. Each of the ADCs may include a counter, and the counter may count the signal received from the CDS circuit to generate a pixel value. For example, the CDS circuit may be implemented by an operational transconductance amplifier (OTA) or a differential amplifier. The counter may be implemented by, for example, an up-counter, an operation circuit, an up/down counter, or a bit-wise inversion counter.

The timing controller 40 may generate timing control signals intended to control the operations of the row driver 20 and the ADC circuit 30. The row driver 20 and the ADC circuit 30 may drive the pixel array 10 in units of rows, as described above, based on the timing control signals issued from the timing controller 40, and may convert the plurality of sensing signals received through the plurality of column lines CL into the pixel values.

The image signal processor 50 may receive first image data IDT1, for example, unprocessed image data, from the ADC circuit 30 and may perform signal processing on the first image data IDT1. For example, the image signal processor 50 may perform signal processing on the first image data IDT1, such as, black level compensation, lens shading compensation, crosstalk compensation, or bad pixel correction.

Second image data IDT2, comprises signal-processed image data output from the image signal processor 50, which may be transmitted to a processor 60. The processor 60 may be a host processor of an electronic device mounted with the image sensor 1.

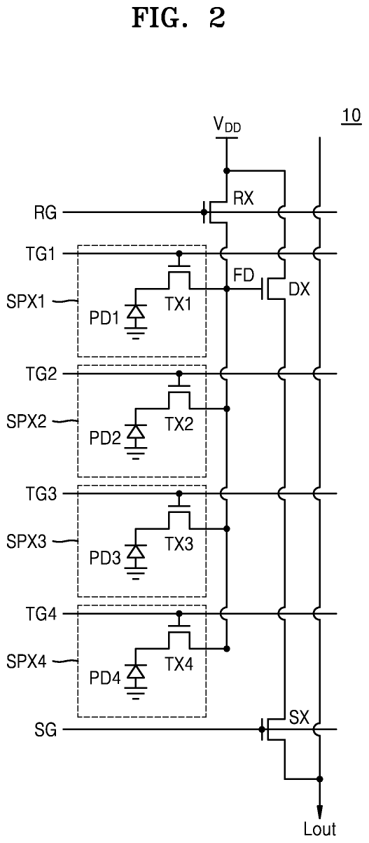

FIG. 2 is a circuit diagram illustrating a plurality of subpixels SPX1, SPX2, SPX3, and SPX4 included in the pixel array 10 of the image sensor 1 according to an embodiment of the inventive concept.

The pixel array 10 may include the plurality of subpixels SPX1, SPX2, SPX3, and SPX4, which may be arranged in a matrix. Each of the plurality of subpixels SPX1, SPX2, SPX3, and SPX4 may generate an electrical signal based on one of blue visible light, green visible light, and red visible light.

The subpixel SPX1 may include a photoelectric conversion element PD1 and a transmission gate TX1. The subpixel SPX2 may include a photoelectric conversion element PD2 and a transmission gate TX2. The subpixel SPX3 may include a photoelectric conversion element PD3 and a transmission gate TX3. The subpixel SPX4 may include a photoelectric conversion element PD4 and a transmission gate TX4.

According to an embodiment, the plurality of subpixels SPX1, SPX2, SPX3, and SPX4 may share logic transistors. For example, the logic transistors that may be shared among the plurality of subpixels SPX1, SPX2, SPX3, and SPX4 may include a reset transistor RX, a selection transistor SX, and a drive transistor DX.

The plurality of photoelectric conversion elements PD1, PD2, PD3, and PD4 may respectively generate and accumulate photocharges in proportion to an amount of external incident light. Each of the plurality of photoelectric conversion elements PD1, PD2, PD3, and PD4 may include a light sensing element including an organic material or an inorganic material, such as an inorganic photodiode, an organic photodiode, a perovskite photodiode, a phototransistor, a photogate, a pinned photodiode, or an organic photoconductive layer.

The plurality of transmission gates TX1, TX2, TX3, and TX4 may transmit charges accumulated in the plurality of photoelectric conversion elements PD1, PD2, PD3, and PD4 to a floating diffusion region FD, based on a plurality of corresponding transmission signals TG1, TG2, TG3, and TG4, respectively. The photocharges generated by the plurality of photoelectric conversion elements PD1, PD2, PD3, and PD4 may be stored in the floating diffusion region FD. The drive transistor DX may be controlled by an amount of the photocharges accumulated in the floating diffusion region FD.

The reset transistor RX may periodically reset charges accumulated in the floating diffusion region FD, based on a reset signal RG. A drain electrode of the reset transistor RX may be connected to the floating diffusion region FD, and a source electrode thereof may be connected to a power supply voltage VDD. When the reset transistor RX is turned on, the power supply voltage VDD connected to the source electrode of the reset transistor RX may be transmitted to the floating diffusion region FD. Therefore, when the reset transistor RX is turned on, the charges accumulated in the floating diffusion region FD may be discharged so that the floating diffusion region FD may be reset.

The drive transistor DX may form a source follower buffer amplifier with a constant current source outside each of the plurality of subpixels SPX1, SPX2, SPX3, and SPX4. The source follower buffer amplifier may amplify a potential change in the floating diffusion region FD and may output the amplified potential change to an output line Lout.

The selection transistor SX may select subpixels SPX to read a photoelectric signal value sensed in units of rows, based on a selection signal SG. When the selection transistor SX is turned on, the power supply voltage VDD may be transmitted to a source electrode of the drive transistor DX.

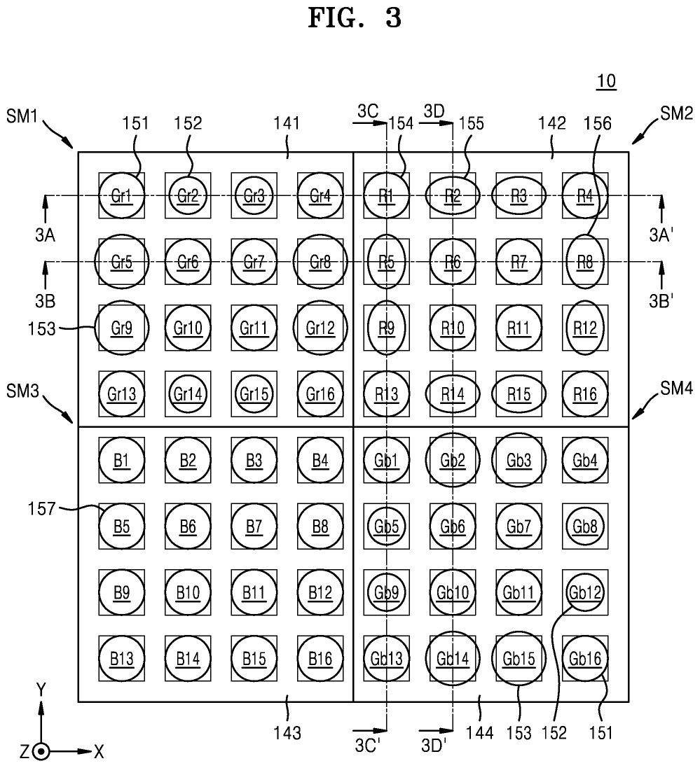

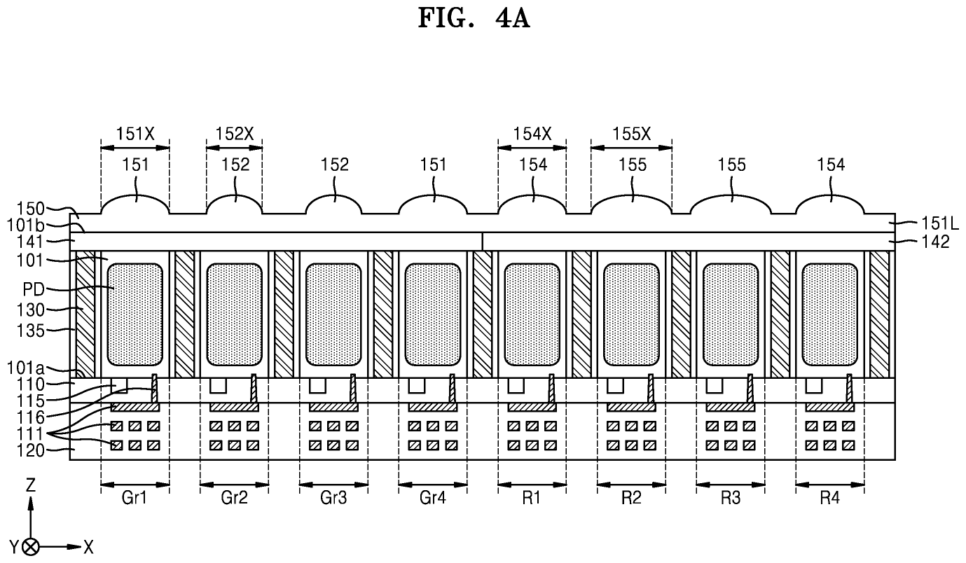

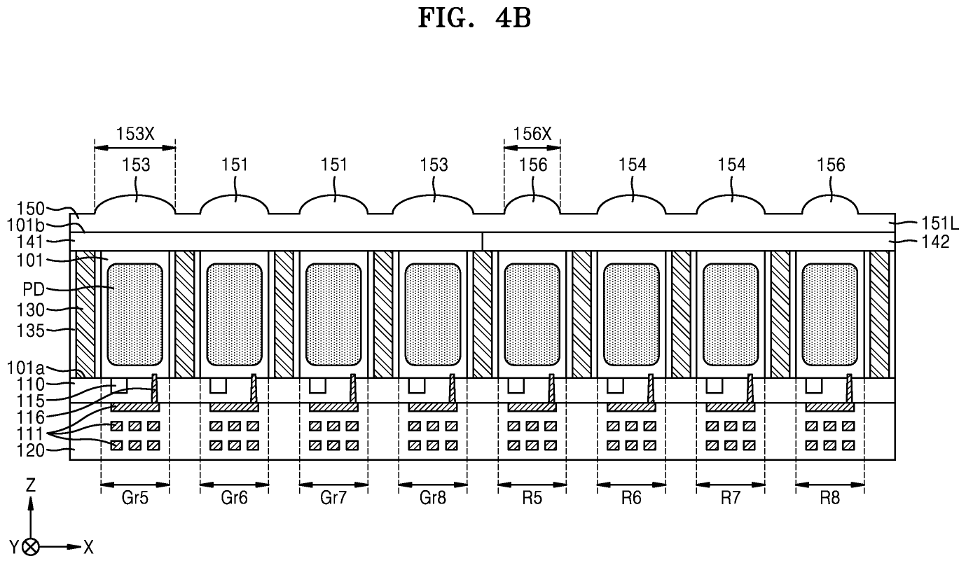

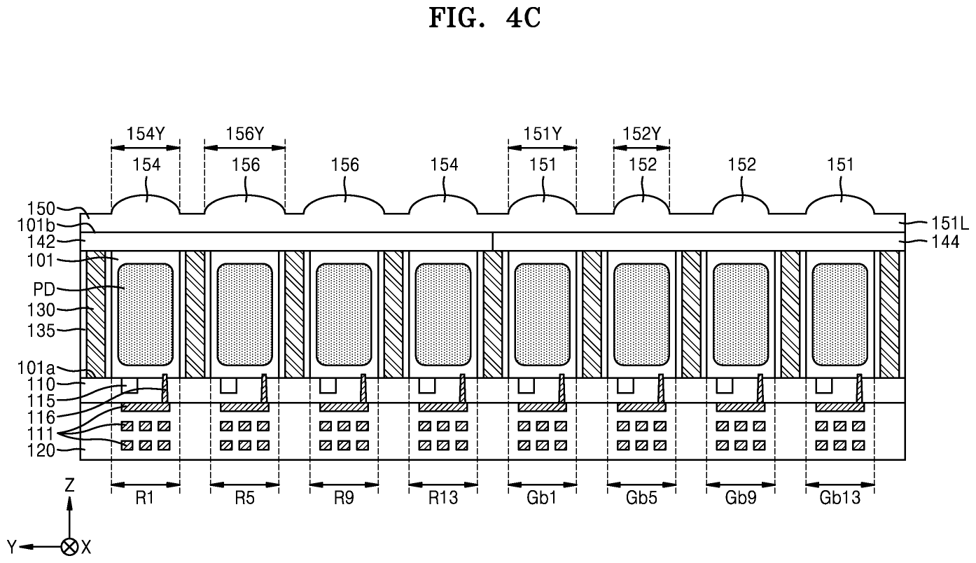

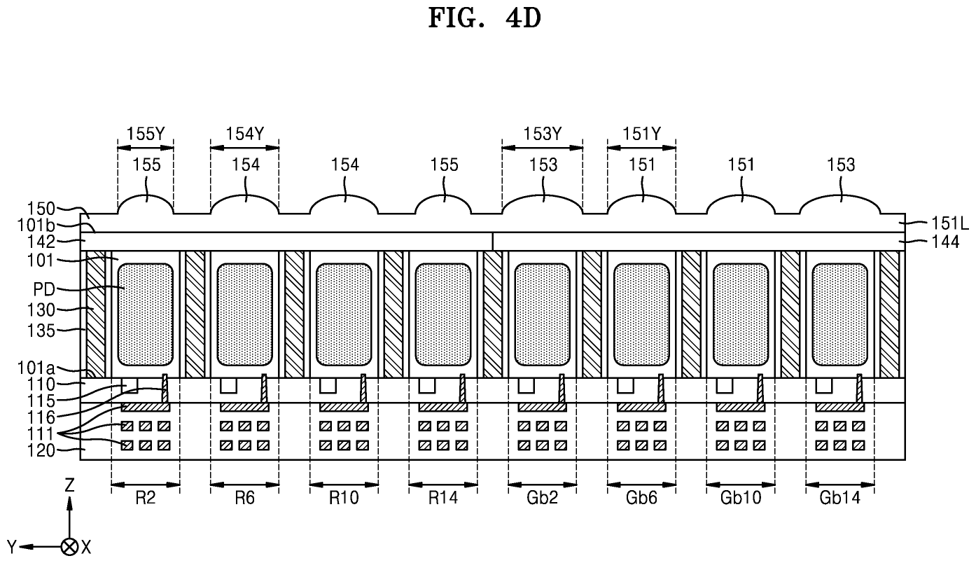

Referring to FIGS. 3 to 4D, the pixel array 10 of the image sensor 11 may include a substrate 101, photoelectric conversion elements PD, gate electrodes 115, an insulating layer 110, contact vias 116, conductive patterns 111, an interlayer insulating layer 120, first and second device isolation layers 130 and 135, first to fourth color filter layers 141, 142, 143, and 144, and a lens layer 150.

The substrate 101 may include a first surface 101a and a second surface 101b facing each other. The first surface 101a of the substrate 101 may be a front surface of the substrate 101, and the second surface 101b of the substrate 101 may be a rear surface of the substrate 101.

Two directions substantially parallel with the first surface 101a and substantially perpendicular to each other are defined herein as an X direction and a Y direction. A direction substantially perpendicular to the first surface 101a is defined herein as a Z direction. The X direction, the Y direction, and the Z direction may be substantially perpendicular to one another.

First to sixteenth green-red subpixels (Gr1 to Gr16), first to sixteenth red subpixels (R1 to R16), first to sixteenth blue subpixels (B1 to B16), and first to sixteenth green-blue subpixels (Gb1 to Gb16) may be formed in the substrate 101. The first to sixteenth green-red subpixels (Gr1 to Gr16), the first to sixteenth red subpixels (R1 to R16), the first to sixteenth blue subpixels (B1 to B16), and the first to sixteenth green-blue subpixels (Gb1 to Gb16) may be arranged in a matrix in a plan view.

The first to sixteenth green-red subpixels (Gr1 to Gr16), the first to sixteenth red subpixels (R1 to R16), the first to sixteenth blue subpixels (B1 to B16), and the first to sixteenth green-blue subpixels Gb1 to Gb16) may have substantially the same horizontal area.

The first to sixteenth green-red subpixels (Gr1 to Gr16), the first to sixteenth red subpixels (R1 to R16), the first to sixteenth blue subpixels (B1 to B16), and the first to sixteenth green-blue subpixels (Gb1 to Gb16) may have substantially the same length in the X direction. The first to sixteenth green-red subpixels (Gr1 to Gr16), the first to sixteenth red subpixels (R1 to R16), the first to sixteenth blue subpixels (B1 to B16), and the first to sixteenth green-blue subpixels (Gb1 to Gb16) may have substantially the same length in the Y direction.

The length of each of the first to sixteenth green-red subpixels (Gr1 to Gr16), the first to sixteenth red subpixels (R1 to R16), the first to sixteenth blue subpixels (B1 to B16), and the first to sixteenth green-blue subpixels (Gb1 to Gb16) in the X direction may be substantially equal to the length of each of the first to sixteenth green-red subpixels (Gr1 to Gr16), the first to sixteenth red subpixels (R1 to R16), the first to sixteenth blue subpixels (B1 to B16), and the first to sixteenth green-blue subpixels (Gb1 to Gb16) in the Y direction.

According to some embodiments, the first device isolation layers 130 of the pixel array 10 may extend among the first to sixteenth green-red subpixels (Gr1 to Gr16), the first to sixteenth red subpixels (R1 to R16), the first to sixteenth blue subpixels (B1 to B16), and the first to sixteenth green-blue subpixels (Gb1 to Gb16) in the X and Y directions. The first device isolation layers 130 may horizontally separate the first to sixteenth green-red subpixels Gr1 to Gr16, the first to sixteenth red subpixels R1 to R16, the first to sixteenth blue subpixels B1 to B16, and the first to sixteenth green-blue subpixels Gb1 to Gb16 that are adjacent to one another.

According to an embodiment, the second device isolation layers 135 of the pixel array 10 may be arranged between the first device isolation layers 130 and the first to sixteenth green-red subpixels (Gr1 to Gr16), between the first device isolation layers 130 and the first to sixteenth red subpixels (R1 to R16), between the first device isolation layers 130 and the first to sixteenth blue subpixels (B1 to B16), and between the first device isolation layers 130 and the first to sixteenth green-blue subpixels (Gb1 to Gb16).

Therefore, the first to sixteenth green-red subpixels (Gr1 to Gr16), the first to sixteenth red subpixels (R1 to R16), the first to sixteenth blue subpixels (B1 to B16), and the first to sixteenth green-blue subpixels (Gb1 to Gb16) may be electrically isolated from one another to operate as separate elements.

The first device isolation layers 130 may include a material having high gap fill performance, for example, polysilicon. According to an embodiment, the first device isolation layers 130 may be doped with p-type dopant, for example, boron (B). However, the inventive concept is not particularly limited thereto. According to some embodiments, each of the first device isolation layers 130 may have a length in the Z direction, which is equal to that of the substrate 101, to separate the plurality of different subpixels Gr1 to Gb16 and dummy pixels.

The second device isolation layers 135 may include an insulating material. According to an example embodiment, the second device isolation layers 135 may include a high dielectric constant material. However, the inventive concept is not particularly limited thereto.

The substrate 101 and the first device isolation layers 130 may operate as electrodes and the second device isolation layers 135 may operate as dielectric layers to operate in the same manner as capacitors. Therefore, a voltage difference between the substrate 101 and the first device isolation layers 130 may be substantially maintained to be constant.

According to an embodiment, a predetermined potential may be applied to the substrate 101 through contact vias 116. According to an embodiment, the potential of the substrate 101 may be a ground potential. However, the inventive concept is not particularly limited thereto. According to an embodiment, a potential that is different from the potential applied to the substrate 101 may be applied to the first device isolation layers 130. According to an embodiment, because the first device isolation layers 130 include doped polysilicon, the first device isolation layers 130 may have substantially the same potential.

According to an embodiment, by applying a voltage lower than that applied to the substrate 101 to the first device isolation layers 130, an energy barrier between the substrate 101 and the first device isolation layers 130 may increase so that dark current may be reduced. Therefore, the reliability of the image sensor 1 may improve.

According to an embodiment, the photoelectric conversion elements PD, for example, photodiodes, may be formed in the substrate 101. The gate electrodes 115 may be apart from one another on the first surface 101a of the substrate 101. For example, each of the gate electrodes 115 may be, a gate electrode of one of the transmission transistor TX, the reset transistor RX, the drive transistor DX, and the selection transistor SX of FIG. 2.

In FIGS. 4A to 4C, the gate electrodes 115 are illustrated as being arranged on the first surface 101a of the substrate 101. However, the inventive concept is not particularly limited thereto. For example, the gate electrodes 115 may be buried in the substrate 101.

The interlayer insulating layer 120 and the conductive patterns 111 may be arranged on the first surface 101a of the substrate 101. The conductive patterns 111 may be covered with the interlayer insulating layer 120. The conductive patterns 111 may be protected and insulated by the interlayer insulating layer 120.

The interlayer insulating layer 120 may include, for example, silicon oxide, silicon nitride, or silicon oxynitride. The conductive patterns 111 may include, for example, aluminum (Al), copper (Cu), tungsten (W), cobalt (CO), or ruthenium (Ru).

The conductive patterns 111 may include a plurality of stacked wiring lines at different levels. In FIGS. 4A to 4D, the conductive patterns 111 are illustrated as including three sequentially stacked layers. However, the inventive concept is not particularly limited thereto. For example, two or four or more layers of conductive patterns 111 may be formed in the interlayer insulating layer 120.

The insulating layer 110 may be arranged between the first surface 101a of the substrate 101 and the interlayer insulating layer 120. The insulating layer 110 may cover the gate electrodes 115 arranged on the first surface 101a of the substrate 101. According to some embodiments, the insulating layer 110 may include an insulating material, such as silicon oxide, silicon nitride, or silicon oxynitride.

The first to fourth color filter layers (141, 142, 143, and 144) may be arranged on the second surface 101b of the substrate 101. The first to fourth color filter layers (141, 142, 143, and 144) may be arranged in a Bayer pattern.

In FIG. 3, for ease of explanation, only the first to fourth color filter layers (141, 142, 143, and 144) are illustrated. However, a person skilled in the art should understand, based on the description, that the pixel array 10 including the first to fourth color filter layers 141, 142, 143, and 144, are repeatedly arranged in the substrate, including their constituent subpixels.

Accordingly, the first color filter layer 141 may be spaced apart from a further first color filter layer that is not shown in the X direction with the second color filter layer 142 shown therebetween. Similarly, the first color filter layer 141 may be spaced apart from another first color filter layer that is not shown in the Y direction with the third color filter layer 143 shown therebetween. The second color filter layer 142 may be spaced apart from another second color filter layer that is not shown in the X direction with the first color filter layer 141 shown therebetween. The second color filter layer 142 may be spaced apart from another second color filter layer that is not shown in the Y direction with the fourth color filter layer 144 shown therebetween. The third color filter layer 143 may be spaced apart from another third color filter layer, that is not shown in the Y direction, with the first color filter layer 141 shown therebetween. The third color filter layer 143 may be spaced apart from another third color filter layer, that is not shown in the Y direction, with the fourth color filter layer 144 therebetween. The fourth color filter layer 144 may be spaced apart from another fourth color filter layer that is not shown in the Y direction with the second color filter layer 142 shown therebetween, and the fourth color filter layer 144 may be spaced apart from another fourth color filter layer, that is not shown in the X direction, with the third color filter layer 143 shown therebetween.

The first color filter layer 141 may have higher transmittance for a green visible light band than for red and blue visible light bands. The second color filter layer 142 may have higher transmittance for a red visible light band than for blue and green visible light bands. The third color filter layer 143 may have higher transmittance for a blue visible light band than for red and green visible light bands. The fourth color filter layer 144 may have higher transmittance for the green visible light band than for the red and blue visible light bands.

The first color filter layer 141 may vertically overlap the first to sixteenth green-red subpixels Gr1 to Gr16. For example, the overlap may be in the Z direction. Similarly, the second color filter layer 142 may vertically overlap the first to sixteenth red subpixels (R1 to R16). The third color filter layer 143 may vertically overlap the first to sixteenth blue subpixels (B1 to B16). The fourth color filter layer 144 may vertically overlap the first to sixteenth green-blue subpixels (Gb1 to Gb16).

According to some embodiments, the first to sixteenth green-red subpixels (Gr1 to Gr16) may share the first color filter layer 141, the first to sixteenth red subpixels (R1 to R16) may share the second color filter layer 142, the first to sixteenth blue subpixels (B1 to B16) may share the third color filter layer 143, and the first to sixteenth green-blue subpixels (Gb1 to Gb16) may share the fourth color filter layer 144.

Therefore, the first to sixteenth green-red subpixels (Gr1 to Gr16) may generate an electrical signal based on the green visible light, the first to sixteenth red subpixels (R1 to R16) may generate an electrical signal based on the red visible light, the first to sixteenth blue subpixels (B1 to B16) may generate an electrical signal based on the blue visible light, and the first to sixteenth green-blue subpixels (Gb1 to Gb16) may generate an electrical signal based on the green visible light.

The first to sixteenth green-red subpixels (Gr1 to Gr16) may form a first submatrix SM1. For example, the first to sixteenth green-red subpixels (Gr1 to Gr16) may be arranged in a 4×4 matrix. Therefore, the first submatrix SM1 may be rectangular.

More specifically, the first to fourth green-red subpixels (Gr1 to Gr4) may be arranged in a first row parallel with the X direction of the first submatrix SM1, the fifth to eighth green-red subpixels (Gr5 to Gr8) may be arranged in a second row parallel with the X direction of the first submatrix SM1, the ninth to twelfth green-red subpixels (Gr9 to Gr12) may be arranged in a third row parallel with the X direction of the first submatrix SM1, and the thirteenth to sixteenth green-red subpixels (Gr13 to Gr16) may be arranged in a fourth row parallel with the X direction of the first submatrix SM1. The first to fourth rows of the first submatrix SM1 may be arranged in the Y direction.

The first submatrix SM1 and the second to fourth submatrices (SM2 to SM4) described in detail further below may respectively comprise a set of the first to sixteenth green-red subpixels (Gr1 to Gr16) sharing the first color filter layer 141, a set of the first to sixteenth red subpixels (R1 to R16) sharing the second color filter layer 142, a set of the first to sixteenth blue subpixels (B1 to B16) sharing the third color filter layer 143, and a set of the first to sixteenth green-blue subpixels (Gb1 to Gb16) sharing the fourth color filter layer 144. For example, the first submatrix SM1 may comprise the set of the first to sixteenth green-red subpixels (Gr1 to Gr16) sharing the first color filter layer 141, the second submatrix SM2 may comprise the set of the first to sixteenth red subpixels (R1 to R16) sharing the second color filter layer 142, the third submatrix SM3 may comprise the set of the first to sixteenth blue subpixels (B1 to B16) sharing the third color filter layer 143, and the fourth submatrix SM4 may comprise the set of the first to sixteenth green-blue subpixels (Gb1 to Gb16) sharing the fourth color filter layer 144.

According to an embodiment, the first to sixteenth red subpixels (R1 to R16), the first to sixteenth blue subpixels (B1 to B16), and the first to sixteenth green-blue subpixels (Gb1 to Gb16) may be arranged similarly to the first to sixteenth green-red subpixels (Gr1 to Gr16), as described above. Therefore, the first to sixteenth red subpixels (R1 to R16) may form the second submatrix SM2, the first to sixteenth blue subpixels (B1 to B16) may form the third submatrix SM3, and the first to sixteenth green-blue subpixels (Gb1 to Gb16) may form the fourth submatrix SM4. The second to fourth submatrices SM2 to SM4 may be rectangular matrices arranged in a 4×4 matrix configuration.

According to an embodiment, the lens layer 150 may include an organic material, such as photosensitive resin or an inorganic material. According to some embodiments, the lens layer 150 may include a base layer 150L and first to seventh group of microlenses 151 to 157. According to an embodiment, the first to seventh group of microlenses 151 to 157 may be arranged on the base layer 150L. According to an embodiment, the first to seventh group of microlenses 151 to 157 may focus incident light on the vertically overlapping photoelectric conversion elements PD, in the Z direction.

According to an embodiment, the first to third group of microlenses 151 to 153 may be arranged on the first color filter layer 141 and the fourth color filter layer 144, the fourth to sixth group of microlenses 154 to 156 may be arranged on the second color filter layer 142, and the seventh group of microlenses 157 may be arranged on the third color filter layer 143.

The first, fourth, sixth, seventh, tenth, eleventh, thirteenth, and sixteenth green-red subpixels Gr1, Gr4, Gr6, Gr7, Gr10, Gr11, Gr13, and Gr16 that are diagonal components of the first submatrix SM1 may vertically overlap the first microlenses 151, respectively. Each of the second, third, fifth, eighth, ninth, twelfth, fourteenth, and fifteenth green-red subpixels Gr2, Gr3, Gr5, Gr8, Gr9, Gr12, Gr14, and Gr15 that are off-diagonal components of the first submatrix SM1 may vertically overlap one of the second and third group of microlenses 152 and 153.

In the first submatrix SM1, the first microlenses 151 may vertically overlap the first, fourth, sixth, seventh, tenth, eleventh, thirteenth, and sixteenth green-red subpixels (Gr1, Gr4, Gr6, Gr7, Gr10, Gr11, Gr13, and Gr16). The first, fourth, thirteenth, and sixteenth green-red subpixels (Gr1, Gr4, Gr13, and Gr16) vertically overlapping the first microlenses 151 may be arranged on corners of the first submatrix SM1 and the sixth, seventh, tenth, and eleventh green-red subpixels (Gr6, Gr7, Gr10, and Gr11) vertically overlapping the first microlenses 151 may be arranged in the center portion of the first submatrix SM1.

In the first submatrix SM1, the second group of microlenses 152 may vertically overlap the second, third, fourteenth, and fifteenth green-red subpixels (Gr2, Gr3, Gr14, and Gr15). The second, third, fourteenth, and fifteenth green-red subpixels (Gr2, Gr3, Gr14, and Gr15) adjacent to the third color filter layer 143 may vertically overlap the second group of microlenses 152, respectively. The second, third, fourteenth, and fifteenth green-red subpixels Gr2, Gr3, Gr14, and Gr15 overlapping the second group of microlenses 152 may be arranged at an edge of the first submatrix SM1. In the first submatrix SM1, the second green-red subpixel Gr2 that is a second component of the first row, the third green-red subpixel Gr3 that is a third component of the first row, the fourteenth green-red subpixel Gr14 that is a second component of the fourth row, and the fifteenth green-red subpixel Gr15 that is a third component of the fourth row may vertically overlap the second group of microlenses 152.

In the first submatrix SM1, the third group of microlenses 153 may vertically overlap the fifth, eighth, ninth, and twelfth green-red subpixels (Gr5, Gr8, Gr9, and Gr12). With overlap being defined in the Z direction. The 5th, eighth, ninth, and twelfth green-red subpixels (Gr5, Gr8, Gr9, and Gr12) adjacent to the second color filter layer 142 may vertically overlap the third group of microlenses 153, respectively. The fifth, eighth, ninth, and twelfth green-red subpixels (Gr5, Gr8, Gr9, and Gr12) overlapping the third group of microlenses 153 may be arranged at an edge of the first submatrix SM1. In the first submatrix SM1, the fifth green-red subpixel Gr5 that is a first component of the second row, the eighth green-red subpixel Gr8 that is a fourth component of the second row, the ninth green-red subpixel Gr9 that is a first component of the third row, and the twelfth green-red subpixel Gr12 that is a fourth component of the third row may vertically overlap the third group of microlenses 153.

In the second submatrix SM2, the first, fourth, sixth, seventh, tenth, eleventh, thirteenth, and sixteenth red subpixels (R1, R4, R6, R7, R10, R11, R13, and R16) that are diagonal components of the second submatrix SM2 may vertically overlap the fourth group of microlenses 154, respectively. Each of the second, third, fifth, eighth, ninth, twelfth, fourteenth, and fifteenth red subpixels (R2, R3, R5, R8, R9, R12, R14, and R15) that are off-diagonal components of the second submatrix SM2 may vertically overlap one of the fifth and sixth group of microlenses 155 and 156.

In the second submatrix SM2, the fourth group of microlenses 154 may vertically overlap the first, fourth, sixth, seventh, tenth, eleventh, thirteenth, and sixteenth red subpixels (R1, R4, R6, R7, R10, R11, R13, and R16). The first, 4th, thirteenth, and sixteenth red subpixels (R1, R4, R13, and R16) vertically overlapping the fourth group of microlenses 154 may be arranged on corners of the second submatrix SM2 and the sixth, seventh, tenth, and eleventh red subpixels (R6, R7, R10, and R11) vertically overlapping the fourth group of microlenses 154 may be arranged at the center portion of the second submatrix SM2.

In the second submatrix SM2, the fifth group of microlenses 155 may vertically overlap the second, third, fourteenth, and fifteenth red subpixels (R2, R3, R14, and R15. The second, third, fourteenth, and fifteenth red subpixels R2, R3, R14, and R15 adjacent to the fourth color filter layer 144 may vertically overlap the fifth group of microlenses 155, respectively. The second, third, fourteenth, and fifteenth red subpixels R2, R3, R14, and R15 overlapping the fifth group of microlenses 155 may be arranged at an edge of the second submatrix SM2. In the second submatrix SM2, the second red subpixel R2 that is a second component of the first row, the third red subpixel R3 that is a third component of the first row, the fourteenth red subpixel R14 that is a second component of the fourth row, and the fifteenth red subpixel R15 that is a third component of the fourth row may vertically overlap the fifth group of microlenses 155.

In the second submatrix SM2, the sixth group of microlenses 156 may vertically overlap the 5th, eighth, ninth, and twelfth red subpixels (R5, R8, R9, and R12). The 5th, eighth, ninth, and twelfth red subpixels (R5, R8, R9, and R12) adjacent to the first color filter layer 141 may vertically overlap the sixth group of microlenses 156, respectively. The 5th, eighth, ninth, and twelfth red subpixels (R5, R8, R9, and R12) overlapping the sixth group of microlenses 156 may be arranged at an edge of the second submatrix SM2. In the second submatrix SM2, the 5th red subpixel R5 that is a first component of the second row, the eighth red subpixel R8 that is a 4th component of the second row, the ninth red subpixel R9 that is a first component of the third row, and the twelfth red subpixel R12 that is a fourth component of the third row may vertically overlap the sixth group of microlenses 156.

In the third submatrix SM3, each of the first to sixteenth blue subpixels B1 to B16 may vertically overlap the seventh group of microlenses 157.

In the fourth submatrix SM4, the green-blue subpixels Gb1, Gb4, Gb6, Gb7, Gb10, Gb11, Gb13, and Gb16 that are diagonal components of the fourth submatrix SM4 may vertically overlap the first microlenses 151, respectively. Each of the green-blue subpixels Gb2, Gb3, Gb5, Gb8, Gb9, Gb12, Gb14, and Gb15 that are off-diagonal components of the fourth submatrix SM4 may vertically overlap one of the second and third group of microlenses 152 and 153.

In the fourth submatrix SM4, the first microlenses 151 may vertically overlap the first, fourth, sixth, seventh, tenth, eleventh, thirteenth, and sixteenth green-blue subpixels (Gb1, Gb4, Gb6, Gb7, Gb10, Gb11, Gb13, and Gb16). The first, fourth, thirteenth, and sixteenth green-blue subpixels (Gb1, Gb4, Gb13, and Gb16) vertically overlapping the first microlenses 151 may be arranged on corners of the fourth submatrix SM4 and the sixth, seventh, tenth, and eleventh green-blue subpixels (Gb6, Gb7, Gb10, and Gb11) vertically overlapping the first microlenses 151 may be arranged in the center portion of the fourth submatrix SM4.

In the fourth submatrix SM4, the second group of microlenses 152 may vertically overlap the fifth, eighth, ninth, and twelfth green-blue subpixels (Gb5, Gb8, Gb9, and Gb12). The 5th, eighth, ninth, and twelfth green-blue subpixels (Gb5, Gb8, Gb9, and Gb12) adjacent to the third color filter layer 143 may vertically overlap the second group of microlenses 152, respectively. The 5th, eighth, ninth, and twelfth green-red subpixels (Gr5, Gr8, Gr9, and Gr12) overlapping the second group of microlenses 152 may be arranged at an edge of the fourth submatrix SM4. In the fourth submatrix SM4, the fifth green-blue subpixel Gb5 that is a first component of the second row, the eighth green-blue subpixel Gb8 that is a fourth component of the second row, the ninth green-blue subpixel Gb9 that is a first component of the third row, and the twelfth green-blue subpixel Gb12 that is a fourth component of the third row may vertically overlap the second group of microlenses 152.

In the fourth submatrix SM4, the third group of microlenses 153 may vertically overlap the 2nd, third, fourteenth, and fifteenth green-blue subpixels (Gb2, Gb3, Gb14, and Gb15). The 2nd, third, fourteenth, and fifteenth green-blue subpixels (Gb2, Gb3, Gb14, and Gb15) adjacent to the second color filter layer 142 may vertically overlap the third group of microlenses 153, respectively. The second, third, fourteenth, and fifteenth green-blue subpixels (Gb2, Gb3, Gb14, and Gb15) overlapping the third group of microlenses 153 may be arranged at an edge of the fourth submatrix SM4. In the fourth submatrix SM4, the second green-blue subpixel Gb2 that is a second component of the first row, the third green-blue subpixel Gb3 that is a third component of the first row, the fourteenth green-blue subpixel Gb14 that is a second component of the fourth row, and the fifteenth green-blue subpixel Gb15 that is a third component of the fourth row may vertically overlap the third group of microlenses 153.

The second group of microlenses 152 may be arranged closer to the third color filter layer 143 than the third group of microlenses 153. The third group of microlenses 153 may be arranged closer to the second color filter layer 142 than the second group of microlenses 152.

The fifth group of microlenses 155 may be arranged closer to the fourth color filter layer 144 than the sixth group of microlenses 156. The sixth group of microlenses 156 may be arranged closer to the first color filter layer 141 than the fifth group of microlenses 155.

According to some embodiments, a horizontal area of each of the second group of microlenses 152 may be less than a horizontal area of each of the first microlenses 151.

According to some embodiments, the horizontal area of each of the second group of microlenses 152 may be equal to or greater than about 95% of the horizontal area of each of the first microlenses 151.

According to some embodiments, the horizontal area of each of the second group of microlenses 152 may be equal to or greater than about 96% of the horizontal area of each of the first microlenses 151.

According to some embodiments, the horizontal area of each of the second group of microlenses 152 may be equal to or greater than about 97% of the horizontal area of each of the first microlenses 151.

According to some embodiments, the horizontal area of each of the second group of microlenses 152 may be equal to or greater than about 98% of the horizontal area of each of the first microlenses 151.

According to some embodiments, a length 152X in the X direction of each of the second group of microlenses 152 may be less than a length 151X in the X direction of each of the first microlenses 151.

According to some embodiments, a length 152Y in the Y direction of each of the second group of microlenses 152 may be less than a length 151Y in the Y direction of each of the first microlenses 151.

According to some embodiments, a horizontal area of each of the third group of microlenses 153 may be greater than the horizontal area of each of the first microlenses 151.

According to some embodiments, the horizontal area of each of the second group of microlenses 152 may be equal to or less than about 105% of the horizontal area of each of the first microlenses 151.

According to some embodiments, the horizontal area of each of the second group of microlenses 152 may be equal to or less than about 104% of the horizontal area of each of the first microlenses 151.

According to some embodiments, the horizontal area of each of the second group of microlenses 152 may be equal to or less than about 103% of the horizontal area of each of the first microlenses 151.

According to some embodiments, the horizontal area of each of the second group of microlenses 152 may be equal to or less than about 102% of the horizontal area of each of the first microlenses 151.

According to some embodiments, a length 153X in the X direction of each of the third group of microlenses 153 may be greater than the length 151X in the X direction of each of the first microlenses 151.

According to some embodiments, a length 153Y in the Y direction of each of the third group of microlenses 153 may be greater than the length 151Y in the Y direction of each of the first microlenses 151.

According to embodiments, the horizontal area of each of the first microlenses 151, a horizontal area of each of the fourth group of microlenses 154, and a horizontal area of each of the seventh group of microlenses 157 may be substantially equal to one another.

According to some embodiments, the length 151X in the X direction of each of the first microlenses 151, a length 154X in the X direction of each of the fourth group of microlenses 154, and a length 157X in the X direction of each of the seventh group of microlenses 157 may be substantially equal to one another.

According to some embodiments, the length 151Y in the Y direction of each of the first microlenses 151, a length 154Y in the Y direction of each of the fourth group of microlenses 154, and a length 157Y in the Y direction of each of the seventh group of microlenses 157 may be substantially equal to one another.

According to some embodiments, the length 151X in the X direction of each of the first microlenses 151 may be substantially equal to the length 151Y in the Y direction of each of the first microlenses 151.

According to some embodiments, the length 152X in the X direction of each of the second group of microlenses 152 may be substantially equal to the length 152Y in the Y direction of each of the second group of microlenses 152.

According to some embodiments, the length 153X in the X direction of each of the third group of microlenses 153 may be substantially equal to the length 153Y in the Y direction of each of the third group of microlenses 153.

According to some embodiments, the length 154X in the X direction of each of the fourth group of microlenses 154 may be substantially equal to the length 154Y in the Y direction of each of the fourth group of microlenses 154.

According to some embodiments, the length 157X in the X direction of each of the seventh group of microlenses 157 may be substantially equal to the length 157Y in the Y direction of each of the seventh group of microlenses 157.

According to some embodiments, a length 155X in the X direction of each of the fifth group of microlenses 155 may be greater than the length 154X in the X direction of each of the fourth group of microlenses 154.

According to some embodiments, the length 155X in the X direction of each of the fifth group of microlenses 155 may be equal to or less than about 105% of the length 154X in the X direction of each of the fourth group of microlenses 154.

According to some embodiments, the length 155X in the X direction of each of the fifth group of microlenses 155 may be equal to or less than about 104% of the length 154X in the X direction of each of the fourth group of microlenses 154.

According to some embodiments, the length 155X in the X direction of each of the fifth group of microlenses 155 may be equal to or less than about 103% of the length 154X in the X direction of each of the fourth group of microlenses 154.

According to some embodiments, the length 155X in the X direction of each of the fifth group of microlenses 155 may be equal to or less than about 102% of the length 154X in the X direction of each of the fourth group of microlenses 154.

According to some embodiments, a length 155Y in the Y direction of each of the fifth group of microlenses 155 may be less than the length 154Y in the Y direction of each of the fourth group of microlenses 154.

According to some embodiments, the length 155Y in the Y direction of each of the fifth group of microlenses 155 may be equal to or greater than about 95% of the length 154Y in the Y direction of each of the fourth group of microlenses 154.

According to some embodiments, the length 155Y in the Y direction of each of the fifth group of microlenses 155 may be equal to or greater than about 96% of the length 154Y in the Y direction of each of the fourth group of microlenses 154.

According to some embodiments, the length 155Y in the Y direction of each of the fifth group of microlenses 155 may be equal to or greater than about 97% of the length 154Y in the Y direction of each of the fourth group of microlenses 154.

According to some embodiments, the length 155Y in the Y direction of each of the fifth group of microlenses 155 may be equal to or greater than about 98% of the length 154Y in the Y direction of each of the fourth group of microlenses 154.

According to some embodiments, a length 156X in the X direction of each of the sixth group of microlenses 156 may be less than the length 154X in the X direction of each of the fourth group of microlenses 154.

According to some embodiments, the length 156X in the X direction of each of the sixth group of microlenses 156 may be equal to or greater than about 95% of the length 154X in the X direction of each of the fourth group of microlenses 154.

According to some embodiments, the length 156X in the X direction of each of the sixth group of microlenses 156 may be equal to or greater than about 96% of the length 154X in the X direction of each of the fourth group of microlenses 154.

According to some embodiments, the length 156X in the X direction of each of the sixth group of microlenses 156 may be equal to or greater than about 97% of the length 154X in the X direction of each of the fourth group of microlenses 154.

According to some embodiments, the length 156X in the X direction of each of the sixth group of microlenses 156 may be equal to or greater than about 98% of the length 154X in the X direction of each of the fourth group of microlenses 154.

According to some embodiments, a length 156Y in the Y direction of each of the sixth group of microlenses 156 may be greater than the length 154Y in the Y direction of each of the fourth group of microlenses 154.

According to some embodiments, the length 156Y in the Y direction of each of the fifth group of microlenses 156 may be equal to or less than about 105% of the length 154Y in the Y direction of each of the fourth group of microlenses 154.

According to some embodiments, the length 156Y in the Y direction of each of the fifth group of microlenses 156 may be equal to or less than about 104% of the length 154Y in the Y direction of each of the fourth group of microlenses 154.

According to some embodiments, the length 156Y in the Y direction of each of the fifth group of microlenses 156 may be equal to or less than about 103% of the length 154Y in the Y direction of each of the fourth group of microlenses 154.

According to some embodiments, the length 156Y in the Y direction of each of the fifth group of microlenses 156 may be equal to or less than about 102% of the length 154Y in the Y direction of each of the fourth group of microlenses 154.

According to some embodiments, the length 155X in the X direction of each of the fifth group of microlenses 155 may be substantially equal to the length 156Y in the Y direction of each of the sixth group of microlenses 156.

According to some embodiments, the length 155Y in the Y direction of each of the fifth group of microlenses 155 may be substantially equal to the length 156X in the X direction of each of the sixth group of microlenses 156.

According to some embodiments, the length 155X in the X direction of each of the fifth group of microlenses 155 may be greater than the length 153X in the X direction of each of the third group of microlenses 153.

According to some embodiments, the length 156Y in the Y direction of each of the sixth group of microlenses 156 may be greater than the length 153Y in the Y direction of each of the third group of microlenses 153.

According to some embodiments, the length 155Y in the Y direction of each of the fifth group of microlenses 155 may be less than the length 152Y in the Y direction of each of the second group of microlenses 152.

According to some embodiments, the length 156X in the X direction of each of the sixth group of microlenses 156 may be greater than the length 153X in the X direction of each of the third group of microlenses 153.

Due to a difference in optical characteristics of green light absorption between the second color filter layer 142 and the third color filter layer 143, there is a difference between the signal characteristics of the 5th, eighth, ninth, and twelfth green-red subpixels (Gr5, Gr8, Gr9, and Gr12) and the second, third, fourteenth, and fifteenth green-blue subpixels (Gb2, Gb3, Gb14, and Gb15) adjacent to the second color filter layer 142 and the signal characteristics of the second, third, fourteenth, and fifteenth green-red subpixels (Gr2, Gr3, Gr14, and Gr15) and the 5th, eighth, ninth, and twelfth green-blue subpixels (Gb5, Gb8, Gb9, and Gb12) adjacent to the third color filter layer 143. More specifically, a green light absorption rate of the second color filter layer 142 transmitting red light is greater than a green light absorption rate of the third color filter layer 143 transmitting blue light.

According to some embodiments, by arranging the third group of microlenses 153, that are relatively large, on both of the 5th, eighth, ninth, and twelfth green-red subpixels (Gr5, Gr8, Gr9, and Gr12) and the second, third, fourteenth, and fifteenth green-blue subpixels (Gb2, Gb3, Gb14, and Gb15) adjacent to the second color filter layer 142 and further arranging the second group of microlenses 152 that are relatively small on both of the second, third, fourteenth, and fifteenth green-red subpixels (Gr2, Gr3, Gr14, and Gr15) and the 5th, eighth, ninth, and twelfth green-blue subpixels (Gb5, Gb8, Gb9, and Gb12) adjacent to the third color filter layer 143, it is possible to reduce signal non-uniformity of the pixel array 10, which is caused by the difference in optical characteristics between the second color filter layer 142 and the third color filter layer 143.

Furthermore, by arranging the filters at an edge of the second color filter layer 142 to be remote from the first and fourth color filter layers 141 and 144, an influence of the second color filter layer 142 on the 5th, eighth, ninth, and twelfth green-red subpixels (Gr5, Gr8, Gr9, and Gr12) and the second, third, fourteenth, and fifteenth green-blue subpixels (Gb2, Gb3, Gb14, and Gb15) adjacent to the second color filter layer 142 may be reduced. Therefore, the reliability of the pixel array 10 and the image sensor 1 including the same may improve.

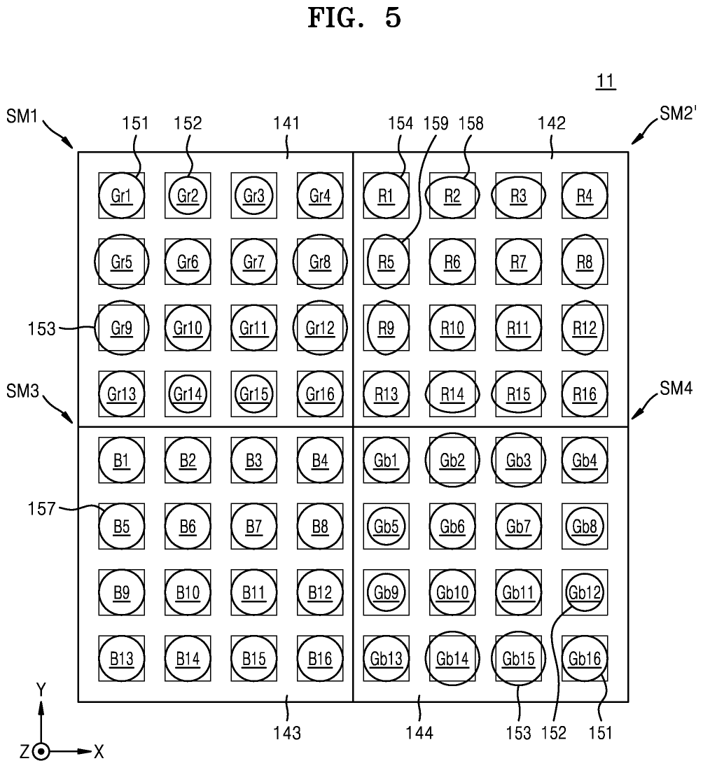

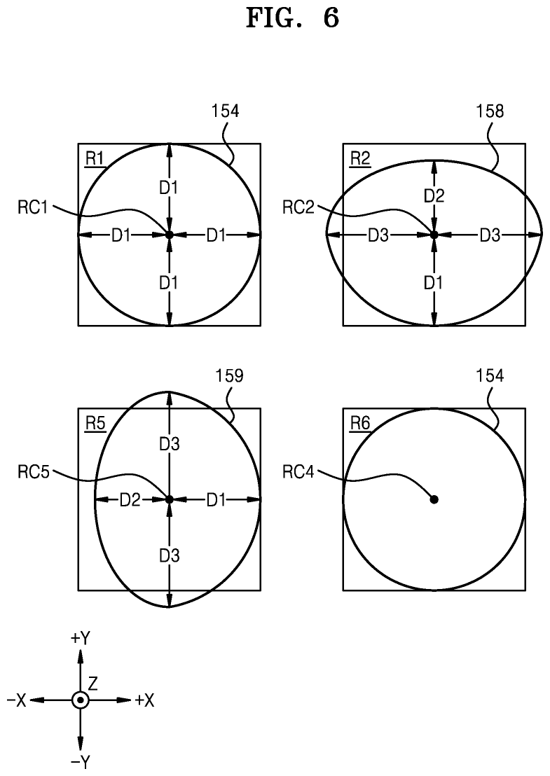

Referring to FIGS. 5 and 6, the pixel array 11 may include a fifth group of microlenses 158 vertically overlapping second, third, fourteenth, and fifteenth red subpixels (R2, R3, R14, and R15) and may further include a sixth group of microlenses 159 vertically overlapping 5th, eighth, ninth, and twelfth red subpixels (R5, R8, R9, and R12).

The pixel array 11 of FIG. 5 may be substantially the same as the pixel array 10 of FIG. 3 except that each of the fifth group of microlenses 155 of pixel array 10, as shown in FIG. 3, is replaced by each of the fifth group of microlenses 158 of pixel array 11, as shown in FIG. 5, and each of the sixth group of microlenses 156 of pixel array 10, as shown in FIG. 3, is replaced by each of the sixth group of microlenses 159 of pixel array 11, as shown in FIG. 5. Therefore, a description of other components of the pixel array 11 except for the fifth and sixth group of microlenses 158 and 159 will be omitted.

In a second submatrix SM2, the fifth group of microlenses 158 may vertically overlap the second, third, fourteenth, and fifteenth red subpixels (R2, R3, R14, and R15). Further, the second, third, fourteenth, and fifteenth red subpixels (R2, R3, R14, and R15) that are arranged adjacent to a fourth color filter layer 144 may respectively vertically overlap the fifth group of microlenses 158. The second, third, fourteenth, and fifteenth red subpixels (R2, R3, R14, and R15) overlapping the fifth group of microlenses 158 may be arranged at an edge of the second submatrix SM2. More particularly, in the second submatrix SM2, the second red subpixel R2 that is a second component of a first row, the third red subpixel R3 that is a third component of the first row, the fourteenth red subpixel R14 that is a second component of a fourth row, and the fifteenth red subpixel R15 that is a third component of the fourth row may vertically overlap the fifth group of microlenses 158.

In the second submatrix SM2, the sixth group of microlenses 159 may respectively vertically overlap the 5th, eighth, ninth, and twelfth red subpixels (5, R8, R9, and R12. The fifth, eighth, ninth, and twelfth red subpixels R5, R8, R9, and R12 adjacent to a first color filter layer 141 may respectively vertically overlap the sixth group of microlenses 156. More particularly, the fifth, eighth, ninth, and twelfth red subpixels R5, R8, R9, and R12 overlapping the sixth group of microlenses 159 may be arranged at an edge of the second submatrix SM2. In the second submatrix SM2, the fifth red subpixel R5 that is a first component of a second row, the eighth red subpixel R8 that is a fourth component of the second row, the ninth red subpixel R9 that is a first component of a third row, and the twelfth red subpixel R12 that is a fourth component of the third row may vertically overlap the sixth group of microlenses 159.

According to an embodiment, fourth group of microlenses 154 may have a symmetrical shape. That is, each of the fourth group of microlenses 154 may be symmetric about axes parallel with the X direction and pass through the centers of first, 4th, sixth, seventh, tenth, eleventh, thirteenth, and sixteenth red subpixels (R1, R4, R6, R7, R10, R11, R13, and R16) vertically overlapping the fourth group of microlenses 154. Each of the fourth group of microlenses 154 vertically overlapping the fourth group of microlenses 154 may be symmetric about axes parallel with the Y direction and pass through the centers of first, fourth, sixth, seventh, tenth, eleventh, thirteenth, and sixteenth red subpixels (R1, R4, R6, R7, R10, R11, R13, and R16).

According to an embodiment, the fifth and sixth group of microlenses 158 and 159 may have an asymmetric shape. That is, the fifth group of microlenses 158 may be asymmetric about an axes parallel with the X direction and pass through the centers of the second, third, fourteenth, and fifteenth red subpixels R2, R3, R14, and R15 vertically overlapping the fifth group of microlenses 158. Each of the sixth group of microlenses 159 may be asymmetric about axes parallel with the Y direction and pass through the centers of the 5th, eighth, ninth, and twelfth red subpixels (R5, R8, R9, and R12) vertically overlapping the sixth group of microlenses 159.

Each of the fifth group of microlenses 158 may be symmetric about axes parallel with the Y direction and pass through the centers of the second, third, fourteenth, and fifteenth red subpixels (R2, R3, R14, and R15) vertically overlapping the fifth group of microlenses 158. Each of the sixth group of microlenses 159 may be symmetric about an axes parallel with the X direction and pass through the centers of the 5th, eighth, ninth, and twelfth red subpixels (R5, R8, R9, and R12) vertically overlapping the sixth group of microlenses 159.

Referring to FIG. 6, the fourth microlens 154 vertically overlapping the first red subpixel R1 may be symmetric about an axis parallel with the X direction and pass through the center RC1 of the first red subpixel R1. As shown in FIG. 6, with all distances measured with respect to the center RC1 of the first red subpixel, the fourth microlens 154 extends a first distance D1 in each of the +/−X and +/−Y directions.

Referring to FIG. 6, the fifth microlens 158 vertically overlapping the second red subpixel R2 may be asymmetric about an axis parallel with the X direction and passing through the center RC2 of the second red subpixel R2. As shown in FIG. 6, with all distances measured with respect to the center RC2 of the second red subpixel R2, the fifth microlens 158 extends a first distance D1 in the −Y direction, a second distance D2 in the +Y direction and a third distance D3 in both the +/−X directions.

Referring to FIG. 6, the sixth microlens 159 vertically overlapping the fifth red subpixel R5 and may be asymmetric about an axis passing through the center RCS of the fifth red subpixel R5 parallel with the X direction. As shown in FIG. 6, with all distances measured with respect to the center RCS of the fifth red subpixel R5, the sixth microlens 159 extends a first distance D1 in the +X direction, a second distance D2 in the +X direction and a third distance D3 in both the +/−Y directions.

In some embodiments, the second distance D2 may be less than the first distance D1. The second distance D2 may be equal to or greater than about 95% of the first distance D1. The second distance D2 may be equal to or greater than about 96% of the first distance D1. The second distance D2 may be equal to or greater than about 97% of the first distance D1. The second distance D2 may be equal to or greater than about 98% of the first distance D1.

In some embodiments, the third distance D3 may be greater than the first distance D1. The third distance D3 may be equal to or less than about 105% of the first distance D1. The third distance D3 may be equal to or less than about 104% of the first distance D1. The third distance D3 may be equal to or less than about 103% of the first distance D1. The third distance D3 may be equal to or less than about 102% of the first distance D1. The third distance D3 may be equal to or less than about 101% of the first distance D1.

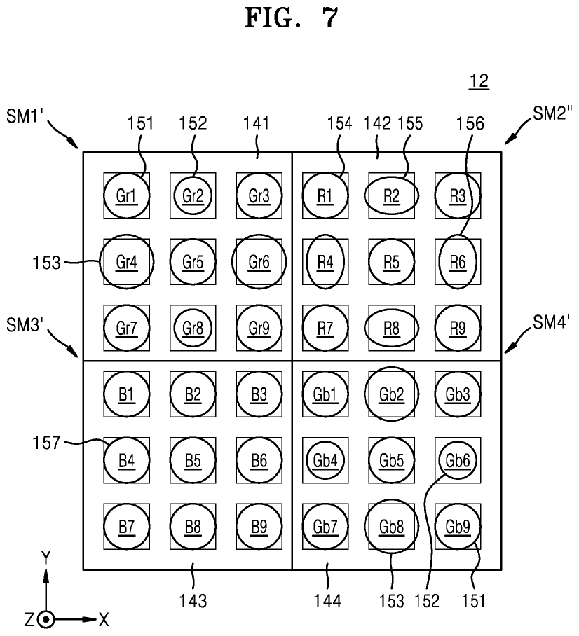

FIG. 7 is a plan view illustrating a pixel array 12 according to an embodiment of the present inventive concept.

Referring to FIG. 7, the pixel array 12 may include a first submatrix SM1′ including first to ninth green-red subpixels (Gr1, Gr2, Gr3, Gr4, Gr5, Gr6, Gr7, Gr8, and Gr9), a second submatrix SM2″ including first to ninth red subpixels (R1, R2, R3, R4, R5, R6, R7, R8, and R9), a third submatrix SM3′ including first to ninth blue subpixels (B1, B2, B3, B4, B5, B6, B7, B8, and B9), and a fourth submatrix SM4′ including first to ninth green-blue subpixels (Gb1, Gb2, Gb3, Gb4, Gb5, Gb6, Gb7, Gb8, and Gb9).

According to the present embodiment, the first, third, fifth, seventh, and ninth green-red subpixels (Gr1, Gr3, Gr5, Gr7, and Gr9) that are diagonal components of the first submatrix SM1′ may respectively vertically overlap the first microlenses 151. Each of the second, fourth, sixth, and eighth green-red subpixels (Gr2, Gr4, Gr6, and Gr8) that are off-diagonal components of the first submatrix SM1′ may vertically overlap one of the second and third group of microlenses 152 and 153.

In the first submatrix SM1′, the first microlenses 151 may vertically overlap the first, third, 5th, seventh, and ninth green-red subpixels (Gr1, Gr3, Gr5, Gr7, and Gr9), respectively. The first, third, seventh, and ninth green-red subpixels (Gr1, Gr3, Gr7, and Gr9) vertically overlapping the first microlenses 151, respectively, may be arranged on corners of the first submatrix SM1′ as shown in FIG. 7 and the fifth green-red subpixel Gr5 vertically overlapping the first microlens 151 may be arranged in the center portion of the first submatrix SM1′.

With continued reference to FIG. 7, in the first submatrix SM1′, the second group of microlenses 152 may vertically overlap the second and eighth green-red subpixels Gr2 and Gr8, respectively. The second and eighth green-red subpixels Gr2 and Gr8 arranged adjacent to a third color filter layer 143 may vertically overlap the second group of microlenses 152, respectively. The second and eighth green-red subpixels Gr2 and Gr8 vertically overlapping the second group of microlenses 152, respectively, may be arranged at an edge of the first submatrix SM1′. More particularly, in the first submatrix SM1′, the second green-red subpixel Gr2 that is a second component of a first row of the first submatrix SM1′ and the eighth green-red subpixel Gr8 that is a second component of a third row of the first submatrix SM1′ may vertically overlap the second group of microlenses 152, respectively.

In the first submatrix SM1′, the third group of microlenses 153 may vertically overlap the fourth and sixth green-red subpixels Gr4 and Gr6, respectively. The fourth and sixth green-red subpixels Gr4 and Gr6 adjacent to a second color filter layer 142 may vertically overlap the third group of microlenses 153, respectively. The fourth and sixth green-red subpixels Gr4 and Gr6 vertically overlapping the third group of microlenses 153, respectively, may be arranged at an edge of the first submatrix SM1′. In the example of FIG. 7, the fourth green-red subpixel Gr4 that is a first component of a second row and the sixth green-red subpixel Gr6 that is a third component of the second row of the first submatrix SM1′ may vertically overlap the third group of microlenses 153, respectively.

The first, third, fifth, seventh, and ninth red subpixels R1, R3, R5, R7, and R9 that are diagonal components of the second submatrix SM2″ may vertically overlap fourth group of microlenses 154, respectively. Each of the second, fourth, sixth, and eighth red subpixels R2, R4, R6, and R8 that are off-diagonal components of the second submatrix SM2″ may vertically overlap one of fifth and sixth group of microlenses 155 and 156.

In the second submatrix SM2″, the fourth group of microlenses 154 may vertically overlap the first, third, fifth, seventh, and ninth red subpixels R1, R3, R5, R7, and R9, respectively. The first, third, seventh, and ninth red subpixels R1, R3, R7, and R9 vertically overlapping the fourth group of microlenses 154, respectively, may be arranged on corners of the second submatrix SM2″ and the fifth red subpixel R5 vertically overlapping the fourth microlens 154 may be arranged in the center portion of the second submatrix SM2″.

In the second submatrix SM2″, the fifth group of microlenses 155 may vertically overlap the second and eighth red subpixels R2 and R8, respectively. The second and eighth red subpixels R2 and R8 adjacent to a fourth color filter layer 144 may vertically overlap the fifth group of microlenses 155, respectively. The second and eighth red subpixels R2 and R8 vertically overlapping the fifth group of microlenses 155, respectively, may be arranged at an edge of the second submatrix SM2″. In the example of FIG. 7, the second red subpixel R2 that is a second component of a first row and the eighth red subpixel R8 that is a second component of a third row of the second submatrix SM2″ may vertically overlap the fifth group of microlenses 155, respectively.

In the second submatrix SM2″, the sixth group of microlenses 156 may vertically overlap the fourth and sixth red subpixels R4 and R6, respectively. The fourth and sixth red subpixels R4 and R6 adjacent to the first color filter layer 141 may vertically overlap the sixth group of microlenses 156, respectively. The fourth and sixth red subpixels R4 and R6 vertically overlapping the sixth group of microlenses 156, respectively, may be arranged at an edge of the second submatrix SM2″. In the example of FIG. 7, the fourth red subpixel R4 that is a first component of a second row and the sixth red subpixel R6 that is a third component of the second row of the second submatrix SM2″ may vertically overlap the sixth group of microlenses 156, respectively.

In the third submatrix SM3′, the first to ninth blue subpixels B1 to B9 may vertically overlap seventh group of microlenses 157, respectively.

According to embodiments, first, third, fifth, seventh, and ninth green-blue subpixels Gb1, Gb3, Gb5, Gb7, and Gb9 that are diagonal components of the fourth submatrix SM4′ may vertically overlap the first microlenses 151, respectively. Each of the second, fourth, sixth, and eighth green-blue subpixels Gb2, Gb4, Gb6, and Gb8 that are off-diagonal components of the fourth submatrix SM4′ may vertically overlap one of the second and third group of microlenses 152 and 153.

In the fourth submatrix SM4′, the first microlenses 151 may vertically overlap the first, third, fifth, seventh, and ninth green-blue subpixels Gb1, Gb3, Gb5, Gb7, and Gb9, respectively. The first, third, seventh, and ninth green-blue subpixels Gb1, Gb3, Gb7, and Gb9 vertically overlapping the first microlenses 151, respectively, may be arranged on corners of the fourth submatrix SM4′ and the fifth green-blue subpixel Gb5 vertically overlapping the first microlens 151 may be arranged in the center portion of the fourth submatrix SM4′.

In the fourth submatrix SM4′, the second group of microlenses 152 may vertically overlap the fourth and sixth green-blue subpixels Gb4 and Gb6, respectively. The fourth and sixth green-blue subpixels Gb4 and Gb6 adjacent to the second color filter layer 142 may vertically overlap the second group of microlenses 152, respectively. The fourth and sixth green-blue subpixels Gb4 and Gb6 vertically overlapping the second group of microlenses 152, respectively, may be arranged at an edge of the fourth submatrix SM4′. In the example of FIG. 7, the fourth green-blue subpixel Gb4 that is a first component of a second row and the sixth green-blue subpixel Gb6 that is a third component of the second row of the fourth submatrix SM4′ may vertically overlap the second group of microlenses 152, respectively.

In the fourth submatrix SM4′, the third group of microlenses 153 may vertically overlap the second and eighth green-blue subpixels Gb2 and Gb8, respectively. The second and eighth green-blue subpixels Gb2 and Gb8 adjacent to the third color filter layer 143 may vertically overlap the third group of microlenses 153, respectively. The second and eighth green-blue subpixels Gb2 and Gb8 vertically overlapping the third group of microlenses 153, respectively, may be arranged at an edge of the fourth submatrix SM4′. In the example of FIG. 7, the second green-blue subpixel Gb2 that is a second component of a first row and the eighth green-blue subpixel Gb8 that is a second component of a third row of the fourth submatrix SM4′ may vertically overlap the third group of microlenses 153, respectively.

Because dimensional characteristics of the first to seventh group of microlenses 151 to 157 are substantially the same as those described with reference to FIGS. 3 to 4D, description thereof will not be given.

In the above, as a non-limiting example, the pixel array 10 (refer to FIG. 3) including the rectangular submatrix consisting of 4×4 subpixels and the pixel array 12 including the rectangular submatrix consisting of 3×3 subpixels are described. A person skilled in the art may easily reach a pixel array including a rectangular submatrix consisting of equal to or greater than 5×5 subpixels based on the above description.

While the present inventive concept has been particularly shown and described with reference to embodiments thereof, it will be understood that various changes in form and details may be made therein without departing from the spirit and scope of the following claims.

What is claimed is:

1. An image sensor comprising:
a substrate having a top surface oriented parallel with each of a co-planar first and second direction;
a plurality of color filter layers comprising a first color filter layer, a second color filter layer, a third color filter layer and a fourth color filter layer,
wherein the plurality of color filter layers are arranged on the substrate to be horizontally adjacent to each other,
wherein the plurality of color filter layers are configured to transmit visible light components of different wavelength bands from incident visible light components passing through the second and third color filter layers; and
a plurality of microlenses including a first group of microlenses, a second group of microlenses, a third group of microlenses, a fourth group of microlenses, a fifth group of microlenses, a sixth group of microlenses and a seventh group of microlenses,
wherein the plurality of microlenses are arranged on the first, second, third and fourth color filter layers,
wherein the substrate comprises:
a plurality of green-red subpixels overlapping the first color filter layer, arranged in a third direction perpendicular to the substrate and forming a first submatrix;
a plurality of red subpixels overlapping the second color filter layer, arranged in the third direction perpendicular to the substrate and forming a second submatrix;
a plurality of blue subpixels overlapping the third color filter layer, arranged in the third direction perpendicular to the substrate and forming a third submatrix; and
a plurality of green-blue subpixels overlapping the fourth color filter layer, arranged in the third direction perpendicular to the substrate and forming a fourth submatrix,
wherein the first microlenses overlap diagonal components of the first submatrix comprised of the green-red subpixels,
wherein the second and third group of microlenses overlap off-diagonal components of the first submatrix comprised of the green-red subpixels,
wherein a horizontal area of each of the second group of microlenses is less than a horizontal area of each of the first microlenses, and
wherein a horizontal area of each of the third group of microlenses is greater than a horizontal area of each of the first microlenses.

2. The image sensor of claim 1, wherein the second group of microlenses are arranged closer to the third color filter layer than the third group of microlenses.

3. The image sensor of claim 1, wherein the third group of microlenses are arranged closer to the second color filter layer than the second group of microlenses.

4. The image sensor of claim 1, wherein a horizontal area of each of the second group of microlenses is equal to or greater than 95% of a horizontal area of each of the first group of microlenses.

5. The image sensor of claim 1, wherein a horizontal area of each of the second group of microlenses is equal to or less than 105% of a horizontal area of each of the first group of microlenses.

6. The image sensor of claim 1, wherein the fourth group of microlenses respectively overlap the green-red subpixels arranged as diagonal components of the first submatrix, wherein the fifth and sixth group of microlenses respectively overlap the green-red subpixels arranged as off-diagonal components of the second submatrix, wherein a length in the first direction of each of the fifth group of microlenses is greater than a length in the second direction of each of the fifth group of microlenses, and
wherein a length in the second direction of each of the sixth group of microlenses is greater than a length in the first direction of each of the sixth group of microlenses.

7. The image sensor of claim 6, wherein a length in the first direction of each of the fifth group of microlenses is greater than a length in the first direction of each of the first group of microlenses, and
wherein a length in the second direction of each of the fifth group of microlenses is less than a length in the second direction of each of the first group of microlenses.

8. The image sensor of claim 7, wherein a length in the first direction of each of the fifth group of microlenses is equal to or less than 105% of a length in the first direction of each of the first group of microlenses.

9. The image sensor of claim 7, wherein a length in the second direction of each of the fifth group of microlenses is equal to or greater than 95% of a length in the second direction of each of the first group of microlenses.

10. The image sensor of claim 6, wherein a length in the second direction of each of the sixth group of microlenses is greater than a length in the second direction of each of the first group of microlenses, and
wherein a length in the first direction of each of the sixth group of microlenses is less than a length in the first direction of each of the first group of microlenses.

11. An image sensor comprising:
a substrate having a top surface parallel with coplanar first and second directions perpendicular to each other,
a plurality of green-red subpixels arranged within the substrate to form a first submatrix, a plurality of red subpixels arranged within the substrate to form a second submatrix, a plurality of blue subpixels arranged within the substrate to form a third submatrix, and a plurality of green-blue subpixels arranged within the substrate to form a fourth submatrix;
a plurality of color filter layers comprising a first color filter layer, a second color filter layer, a third color filter layer and a fourth color filter layer, wherein the plurality of color filter layers are arranged on the substrate adjacent to one another; and
a plurality of microlenses comprising a first group, a second group, a third group, a fourth group, a fifth group, a sixth group and a seventh group of microlenses arranged on the first, second, third and fourth color filter layers,
wherein the fourth group of microlenses vertically overlap diagonal components of the second submatrix comprised of the plurality of red subpixels,
wherein the fifth group of microlenses and sixth group of microlenses vertically overlap off-diagonal components of the second submatrix among the plurality of red subpixels,
wherein a length in the first direction of each of the fourth group of microlenses is substantially equal to a length in the second direction of each of the fourth group of microlenses,
wherein a length in a first direction of each of the fifth group of microlenses is greater than a length in a second direction of each of the fifth group of microlenses, and
wherein a length in the second direction of each of the sixth group of microlenses is greater than a length in the first direction of each of the sixth group of microlenses.

12. The image sensor of claim 11, wherein the first group of microlenses vertically overlap diagonal components of the first submatrix comprised of the plurality of green-red subpixels,
wherein the second group of microlenses and third group of microlenses vertically overlap off-diagonal components of the first submatrix among the plurality of green-red subpixels,
wherein a horizontal area of each of the second group of microlenses is less than a horizontal area of each of the first group of microlenses, and
wherein a horizontal area of each of the third group of microlenses is greater than a horizontal area of each of the first group of microlenses.

13. The image sensor of claim 12, wherein a length in the first direction of each of the first group of microlenses is equal to a length in the first direction of each of the fourth group of microlenses, and
wherein a length in the second direction of each of the first group of microlenses is equal to a length in the second direction of each of the fourth group of microlenses.

14. The image sensor of claim 13, wherein a length in the first direction of each of the fifth group of microlenses is greater than a length in the first direction of each of the first group of microlenses, and
wherein a length in the second direction of each of the sixth group of microlenses is greater than a length in the second direction of each of the first microlenses.

15. The image sensor of claim 13, wherein a length in the second direction of each of the fifth group of microlenses is less than a length in the second direction of each of the first group of microlenses, and
wherein a length in the first direction of each of the sixth group of microlenses is less than a length in the first direction of each of the first group of microlenses.

16. The image sensor of claim 13, wherein a length in the first direction of each of the fifth group of microlenses is greater than a length in the first direction of each of the third group of microlenses, and
wherein a length in the second direction of each of the fifth group of microlenses is less than a length in the second direction of each of the second group of microlenses.

17. The image sensor of claim 13, wherein a length in the first direction of each of the sixth group of microlenses is less than a length in the first direction of each of the second group of microlenses, and
wherein a length in the second direction of each of the sixth group of microlenses is greater than a length in the second direction of each of the third group of microlenses.

18. An image sensor comprising:
a first color filter layer configured to transmit green light;
a second color filter layer configured to transmit red light;
a third color filter layer configured to transmit blue light;
a fourth color filter layer configured to transmit green light;
a first group of microlenses, a second group of microlenses and a third group of microlenses, wherein the first, second and third group of microlenses are arranged on the first and fourth color filter layers; and
a fourth group of microlenses, a fifth group of microlenses, and a sixth group of microlenses, wherein the fourth, fifth and sixth group of microlenses are arranged on the second color filter layer,
wherein the first, second, third and fourth color filter layers are arranged in a matrix extending in first and second coplanar directions,
wherein the third group of microlenses are arranged closer to the second color filter layer than the second group of microlenses,
wherein the second group of microlenses are arranged closer to the third color filter layer than the third group of microlenses,
wherein a horizontal area of each of the third group of microlenses is greater than a horizontal area of each of the first group of microlenses, and
wherein a horizontal area of each of the second group of microlenses is less than a horizontal area of each of the first group of microlenses.

19. The image sensor of claim 18, wherein the first group of microlenses are adjacent to corners of each of the first and fourth color filter layers, wherein the second group of microlenses
are adjacent to edges of the first color filter layer parallel with the first direction and edges parallel of the fourth color filter layer with the second direction, and wherein the third group of
microlenses are adjacent to edges of the first color filter layer parallel with the second direction and edges of the fourth color filter layer parallel with the first direction.

20. The image sensor of claim 18, wherein a length in the first direction of each microlens of the fifth group of microlenses is greater than a length in the first direction of each microlens
of the third group of microlenses, wherein a length in the second direction of each microlens of the fifth group of microlenses is less than a length in the second direction of each microlens
of the second group of microlenses, wherein a length in the first direction of each microlens of the sixth group of microlenses is less than a length in the first direction of each microlens of
the second group of microlenses, and wherein a length in the second direction of each microlens of the sixth group of microlenses is greater than a length in the second direction of each
microlens of the third group of microlenses.
